(19) United States
(12) Patent Application Publication
(10) Pub. No.: US 2020/0203218 A1
(43) Pub. Date: Jun. 25, 2020

(54) SEMICONDUCTOR DEVICE AND FABRICATION METHOD THEREOF

(71) Applicants: Semiconductor Manufacturing International (Shanghai) Corporation, Shanghai (CN); Semiconductor Manufacturing International (Beijing) Corporation, Beijing (CN)

(72) Inventor: Fei ZHOU, Shanghai (CN)

(21) Appl. No.: 16/601,750

(22) Filed: Oct. 15, 2019

(30) Foreign Application Priority Data
Dec. 21, 2018 (CN) 201811570286.1

(51) Int. Cl. H01L 21/768; H01L 29/40; H01L 29/417

(52) U.S. Cl. CPC H01L 21/76804; H01L 29/401; H01L 29/785; H01L 21/76831; H01L 29/41791

(57) ABSTRACT

Fabrication method and semiconductor device are provided. The method includes: providing a substrate; forming gate structures on the substrate and source/drain doped layers in the substrate at sides of each gate structure; forming a dielectric layer on the substrate to cover the gate structures and the source/drain doped layers; forming a first groove in the dielectric layer on each source/drain doped layer with a bottom surface lower than top surfaces of the gate structures; forming first spacers on sidewalls of each first groove with a dielectric constant larger than a dielectric constant of the dielectric layer; forming a second groove in the dielectric layer beneath the bottom surface of each first groove connected to a corresponding first groove and exposing a corresponding source/drain doped layer; and forming a plug in each first groove and the corresponding second groove.

### CROSS-REFERENCES TO RELATED APPLICATION

This application claims the priority of Chinese Patent Application No. 201811570286.1, filed on Dec. 21, 2018, the content of which is incorporated herein by reference in its entirety.

### TECHNICAL FIELD

The present disclosure generally relates to the field of semiconductor technology and, more particularly, relates to a semiconductor device and its fabrication method.

### BACKGROUND

As semiconductor technologies develop quickly, semiconductor devices are developed toward a direction with a higher device density and a higher integration level. A transistor is one of the most fundamental devices and is widely used. With developments of the semiconductor technologies, a controlling ability of a conventional planar transistor on channel currents becomes weaker, causing short channel effects and serious leakage current problems. The semiconductor device has a poor performance.

To better alleviate the short channel effects and suppress the leakage currents, fin field-effect transistors (FinFETs) are widely used. A FinFET is a multi-gate device, and usually includes: fins on a surface of a semiconductor substrate; an isolation layer on the surface of the semiconductor substrate covering a portion of sidewalls of the fins and with a top surface lower than top surfaces of the fins; gate structures on the top surface of the isolation layer, on tops of the fins, and on the sidewalls of the fins; and sources and drains in the fins on two sides of each of the gate structures.

However, the formed FinFETs have poor performances.

### SUMMARY

One aspect of the present disclosure provides a fabrication method for a semiconductor device. The method includes: providing a substrate; forming gate structures on the substrate and source/drain doped layers in the substrate at sides of each gate structure; forming a dielectric layer on the substrate to cover the gate structures and the source/drain doped layers; forming a first groove in the dielectric layer on each source/drain doped layer, wherein the first groove has a bottom surface lower than top surfaces of the gate structures; forming first spacers on sidewalls of each first groove, wherein the first spacers have a dielectric constant larger than a dielectric constant of the dielectric layer; forming a second groove in the dielectric layer beneath the bottom surface of each first groove, wherein each first groove is connected to a corresponding second groove and exposes a corresponding source/drain doped layer, and forming a plug in each first groove and the corresponding second groove.

Another aspect of the present disclosure provides a semiconductor device. The device includes: a substrate; gate structures on the substrate; source/drain doped layers in the substrate at sides of each gate structure; a dielectric layer on the substrate covering the gate structures and the source/drain doped layers; a first groove in the dielectric layer above each source/drain doped layer, wherein the first groove has a bottom surface lower than top surfaces of the gate structures; first spacers on sidewalls of each first groove, wherein the first spacers have a dielectric constant larger than a dielectric constant of the dielectric layer; a second groove in the dielectric layer beneath the bottom surface of each first groove, wherein each first groove is connected to a corresponding second groove and exposes a corresponding source/drain doped layer; and a plug in each first groove and the corresponding second groove.

Other aspects or embodiments of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates semiconductor structures corresponding to certain stages for forming a FinFET device;

FIGS. 2-7 illustrate semiconductor structures corresponding to certain stages for forming an exemplary FinFET according to various disclosed embodiments of the present disclosure; and

FIG. 8 illustrates an exemplary method for forming a FinFET device according to various disclosed embodiments of the present disclosure.

### DETAILED DESCRIPTION

Reference will now be made in detail to exemplary embodiments of the disclosure, which are illustrated in the accompanying drawings. Hereinafter, embodiments consistent with the disclosure will be described with reference to drawings. In the drawings, the shape and size may be exaggerated, distorted, or simplified for clarity. Wherever possible, the same reference numbers will be used throughout the drawings to refer to the same or like parts, and a detailed description thereof may be omitted.

Further, in the present disclosure, the disclosed embodiments and the features of the disclosed embodiments may be combined under conditions without conflicts. It is apparent that the described embodiments are some but not all of the embodiments of the present disclosure. Based on the disclosed embodiments, persons of ordinary skill in the art may derive other embodiments consistent with the present disclosure, all of which are within the scope of the present disclosure.

Moreover, the present disclosure is described with reference to schematic diagrams. For the convenience of descriptions of the embodiments, the cross-sectional views illustrating the device structures may not follow the common proportion and may be partially exaggerated. Besides, those schematic diagrams are merely examples, and not intended to limit the scope of the disclosure. Furthermore, a three-dimensional (3D) size including length, width and depth should be considered during practical fabrication.

The FinFETs formed by the current technologies have poor performances.

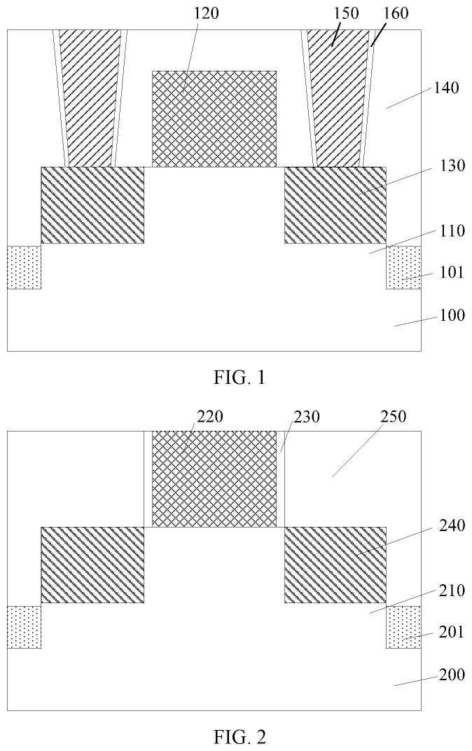

FIG. 1 illustrates a semiconductor device. The semiconductor device includes a substrate 100, fins 110 on a surface of the substrate 100, an isolation layer on a surface of the substrate 100 covering a portion of sidewalls of the fins 110, gate structures 120 crossing the fins 110, source/drain doped layers in the fins 110 at sides of each of the gate structures 120; a dielectric layer 140 on the substrate 100 covering top surfaces of the source/drain doped layers 130, sidewalls and top surfaces of the gate structures 120; conductive structures 150 in the dielectric layer being connected to the source/drain doped layers 130 to cover a portion of top surfaces and sidewalls of the source/drain doped layer 130; and first spacers 160 on sidewalls of the conductive structures 150.

In the semiconductor device, the conductive structures 150 may be formed by: forming grooves in the dielectric layer 140; and forming a conductive structure 150 in each groove. When using an etching process to form the grooves, a size of a top of the grooves is larger than a size of a bottom of the grooves and sidewalls of the grooves are inclined. Correspondingly, a size of the conductive structures decreases gradually from a top to a bottom of the conductive structure, and the size of the conductive structures decreases gradually from a top to a bottom of the gate structures 120. A minimum distance between each of the gate structure 120 and corresponding one conductive structure 150 may be a distance between the top of the one gate structure 120 and the corresponding one conductive structure 150. Each of the gate structure 120 and the corresponding one conductive structure 150 may be isolated from each other by the dielectric layer 140. To better isolating each of the gate structure 120 and the corresponding one conductive structure 150, the first spacers 160 are formed on the sidewalls of the conductive structures 150. The first spacers 160 are made of SiN having a dielectric constant higher than a dielectric constant of SiO2 and have a good isolation performance. However, the dielectric constant of SiNx is too high and a parasitic capacitance between each of the gate structure 120 and the corresponding one conductive structure 150 is large correspondingly. The semiconductor device has a poor performance.

The present disclosure provides a semiconductor device and fabrication method thereof to at least partially resolved above problems. In the fabrication method, first grooves may be formed in a dielectric layer with bottoms lower than top surfaces of gate structures, and first spacers may be formed on sidewalls of the first grooves with a dielectric constant higher than a dielectric constant of the dielectric layer. Then a second groove may be formed in the dielectric layer under the bottom of each first groove, ad each second groove may be connected to a corresponding first groove. A plug may be formed in each first groove and a corresponding second groove. And the plug may be connected to a corresponding source/drain doped layer. The gate structures may be isolated from the plugs in the first grooves by the dielectric layer and the first spacers and the isolation performance may be good. A parasitic capacitance between the gate structures and the plugs in the first grooves may be a first capacitance, while a parasitic capacitance between the gate structures and the plugs in the second grooves may be a second capacitance. A parasitic capacitance between the gate structures and the plugs may be a sum of the first capacitance and the second capacitance. Since each gate structure may be isolated from the plug in a corresponding second groove by the dielectric layer, the second capacitance may be small and correspondingly the parasitic capacitance between the gate structures and the plugs may be small. The performance of the formed semiconductor device may be improved.

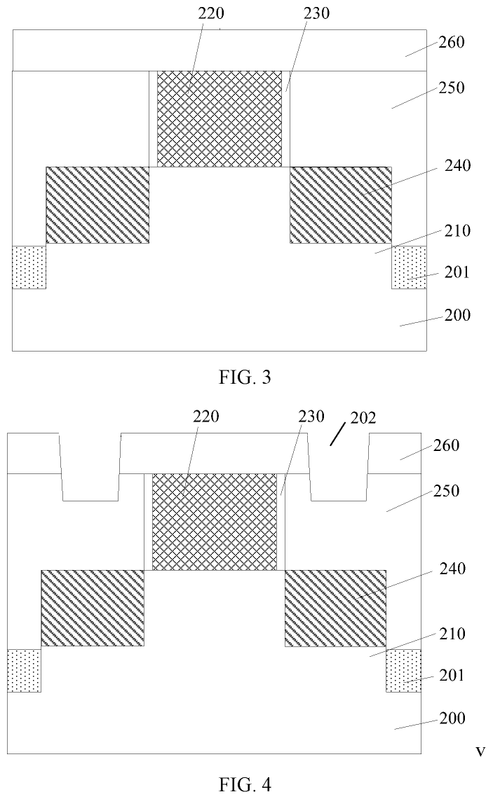

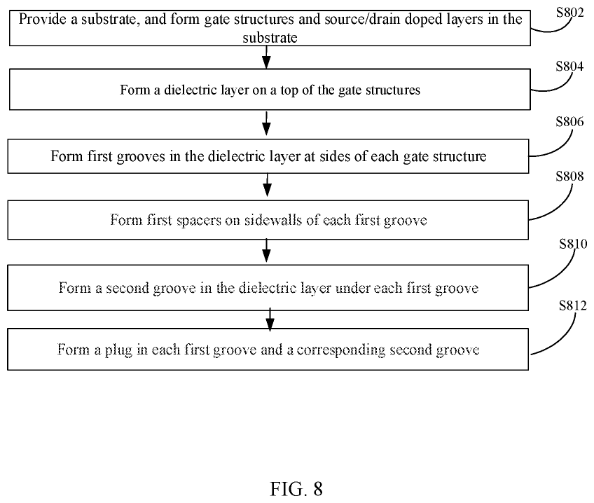

FIGS. 2-7 illustrate semiconductor structures corresponding to certain for forming a FinFET device according to various disclosed embodiments of the present disclosure, and FIG. 8 illustrates an exemplary method for forming a FinFET device according to various disclosed embodiments of the present disclosure.

Referring to FIG. 2, a substrate 200 may be provided (e.g., Step S802 in FIG. 8).

The substrate 200 may be made of silicon, germanium, SiGe, GaAs, AsInGa, and other semiconductor materials. Silicon may be singlycrystalline silicon, polysilicon, and/or amorphous silicon. The substrate 200 may also be a semiconductor structure on an insulator. The semiconductor structure on an insulator may include an insulator and a semiconductor material layer on the insulator. The semiconductor material layer may be made of silicon, germanium, SiGe, GaAs, AsInGa, and other semiconductor materials.

In one embodiment, the substrate 200 may be made of singlecrystalline silicon.

Gate structures 220 may be formed on the substrate 200 and source/drain doped layers 240 may be formed on the substrate at sides of each gate structure 200.

In one embodiment, the method may further include forming fins 210 on the substrate 200. The gate structures 220 may cross the fins 210 and cover a portion of the tops and sidewalls of the fins 210. The source/drain layers 240 may be formed in the fins 210 at sides of each gate structure 220.

In one embodiment, the fins 210 may be formed by patterning the substrate 200.

In some other embodiment, a fin material layer may be formed on the substrate 200 and the fins 210 may be formed by patterning the fin material layer.

In one embodiment, the method may further include forming an isolation layer 201 on the substrate to cover a portion of the sidewalls of the fins 210. The isolation layer 201 may be made of a material including SiO₂.

In one embodiment, each of the gate structures 220 may include a gate dielectric layer and a gate layer on the gate dielectric layer. The gate dielectric layer may be made of a high-k material with k larger than 3.9. The gate layer may be made of a metal such as tungsten.

A gate protective layer may be formed on each of the gate structures 220.

In one embodiment, spacers 230 may be formed on sidewalls of the gate structures 220. The spacers 230 may protect the gate structures 220.

A first dielectric layer 250 may be formed on the substrate 200, to cover the sidewalls of the gate structures 220 and top surfaces of the source/drain doped layers 240.

The gate structures 220 may be formed by: forming dummy gate structures on the substrate 200 crossing the fins 210 to cover a portion of the sidewalls and the top of the fins 210; forming the first dielectric layer 250 covering the substrate 200, the top and the sidewalls of the fins 210, and sidewalls of the dummy gate structures, where the first dielectric layer 250 may have a top flush with top surfaces of the dummy gate structures; removing the dummy gate structures to forming gate openings in the first dielectric layer 250 after forming the first dielectric layer 250; and forming the gate structures 220 in the gate openings.

In one embodiment, the method may further include forming the source/drain doped layers 240 in the fins 210 at sides of each of the dummy gate structures, before forming the first dielectric layer 250.

The source/drain doped layers 240 may be formed by an epitaxial process or an ion implantation process.

In one embodiment, the source/drain doped layers 240 may be formed by the epitaxial process. The source/drain doped layers 240 may be formed by forming first grooves at the sides of each of the fins 210 and forming the source/drain doped layers 240 in the first grooves.

In some other embodiments, the source/drain doped layers 240 may be formed by the ion implantation process. The source/drain doped layers 240 may be formed by performing the ion implantation process on the fins at the sides of each of the dummy gate structures.

In one embodiment, a protective layer may be formed on each of the source/drain doped layers 240. The protective layer may protect a corresponding source/drain doped layer 240 when forming other type source/drain doped layers.

The protective layers may be made of a material different from the dielectric layer. The protective layers may be made of a material including SiN, SiNO, SiCO, SiCN, and/or SiCNO.

In one embodiment, the protective layers may be made of SiN, and the dielectric layer may be made of SiO₂. SiN may have a good etching selection ratio corresponding to SiO₂. Correspondingly, when etching the dielectric layer later, SiN may be etched less while SiO₂ may be removed. The source/drain doped layers may be protected.

The source/drain doped layers 240 may include source/drain ions.

When the semiconductor device is N-type, the source/drain ions may be N conducting type such as phosphor ions. When the semiconductor device is P-type, the source/drain ions may be P conducting type such as boron ions.

The first dielectric layer 250 may be made of a material including SiO₂, SiN, SiNB, SiCNO, and/or SiNO.

In one embodiment, the first dielectric layer 250 may be made of SiO₂.

As illustrated in FIG. 3, a second dielectric layer 260 may be formed on the top of the gate structures 220 and a top of the first dielectric layer 250 (e.g., Step S804 in FIG. 8).

In one embodiment, the dielectric layer may include the first dielectric layer 250 and the second dielectric layer 260. The first dielectric layer 250 may cover the sidewalls of the gate structures 220 and the top of the source/drain doped layer. The second dielectric layer 260 may cover the top of the gate structures 220.

The second dielectric layer 260 may be used to achieve a interlayer isolation.

The second dielectric layer 260 may be made of a material including SiO₂, SiN, SiNB, SiCNO, and/or SiNO.

In one embodiment, the second dielectric layer 260 may be made of SiO₂.

The second dielectric layer 260 may be formed by a chemical vapor deposition method, a physical vapor deposition method, and/or an atomic layer deposition method.

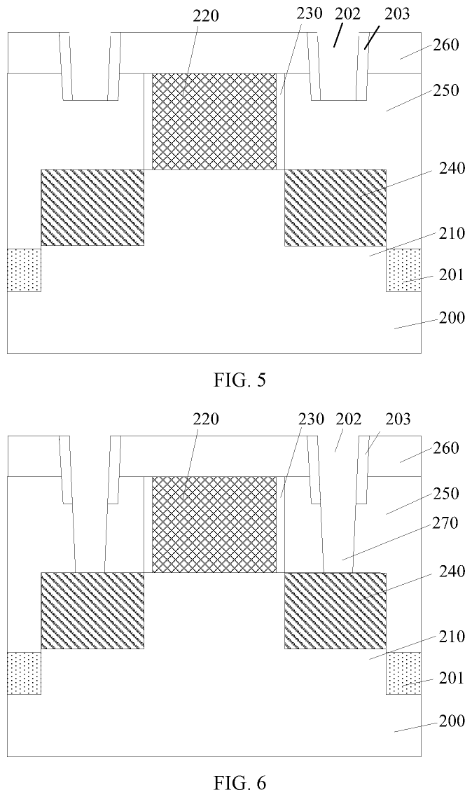

As illustrated in FIG. 4, a first groove 202 may be formed in the dielectric layer on the top of each of the source/drain doped layers 240 (e.g., in Step S806 in FIG. 8). Each first groove 202 may have a bottom surface lower than the top of the gate structures 220.

The first grooves 202 may be formed by: forming a pattern layer (not shown in the figures) on a top of the second dielectric layer 260 exposing a portion of the second dielectric layer 260; and etching the second dielectric layer 260 and the first dielectric layer 250 to form the first grooves in the dielectric layer by using the pattern layer as a mask.

In one embodiment, for each first groove 202, a top dimension may be larger than a bottom dimension and the sidewalls may be inclined. Correspondingly, a size of a plug in each first groove 220 may decreases gradually from a top to a bottom.

A distance between the bottom of the first grooves 202 to the top of the gate structures 220 may be a first distance. The first distance may be about 8 nm to about 25 nm.

First spacers 203 may be formed on the sidewalls of the first grooves 202 and a plug may be formed in each of the first grooves 202. The plugs in the first grooves 202 may be isolated from the gate structures 220 by the first dielectric layer 250 and the first spacers 203. The first spacers 203 may have a dielectric constant larger than a dielectric constant of the dielectric layer, and an isolation performance may be good.

If the first distance is too large, an improvement on the parasitic capacitance between the gate structures 220 and the plugs may be limited. If the first distance is too small, the isolation between the plugs and the top of the gate structures 220 may be not good.

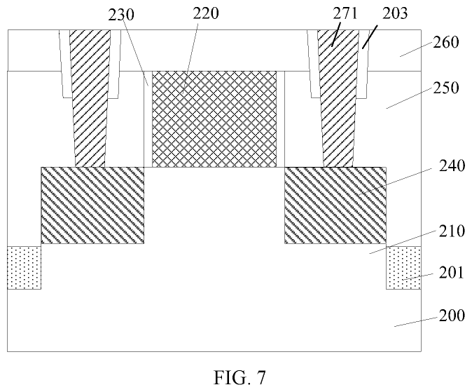

As illustrated in FIG. 5, first spacers 203 may be formed on the sidewalls of each of the first grooves 202 (e.g., Step S808 in FIG. 8). The first spacers 203 may have a dielectric constant larger than a dielectric constant of the dielectric layer.

The first spacers 203 may be used to isolate the gate structures and the plugs.

The first spacers 203 may be made a material including SiO₂, SiN, SiNB, SiCNO, and/or SiNO.

The first spacers 203 may be formed by: forming a first spacer material layer in the first grooves 202 and on the dielectric layer; and etching back the first spacer material layer to expose the top of the dielectric layer and form the first spacers 203.

In one embodiment, the first spacer material layer may be formed in the first grooves 202 and on the second dielectric layer 260.

In one embodiment, the first spacers 203 may be made of SiN.

The first spacers 203 may be made of SiN and the dielectric layer may be made of SiO₂. A plug may be formed in each of the first grooves 202. The plugs in the first grooves 202 may be isolated from the gate structures 220 by the dielectric layer and the first spacers 203. SiN may have a dielectric constant lager than a dielectric constant of SiO₂, and an isolation performance may be good.

The first spacers 203 may have a thickness of about 3 nm to about 6 nm.

If the thickness of the first spacers 203 is too small, the isolation between the gate structures 220 and the plugs may be not good. If the thickness of the first spacers 203 is too large, a size of the plugs may be small and the parasitic capacitance between the plugs and the source/drain doped layers 240 may be large, to make a performance of the semiconductor device bad.

As illustrated in FIG. 6, after forming the first spacers 203, a second groove 270 may be formed in the dielectric layer under the bottom of each first groove 202 (e.g., Step S810 in FIG. 8). Each second groove 270 may be connected to a corresponding first groove 202 and expose a corresponding source/drain doped layer 240.

The second grooves 270 may be formed by etching the dielectric layer under the bottom of each first groove 202 to expose the corresponding source/drain doped layer 240 and to form the second groove 270 in the dielectric layer, by using the first spacers 203 as a mask.

In one embodiment, for each second groove 270, a top dimension may be larger than a bottom dimension and the sidewalls may be inclined. Correpsondingly, a size of a plug in each second groove 270 may decreases gradually from a top to a bottom.

A distance between the bottom of the first grooves 202 to the top of the gate structures 220 may be a first distance. A ratio between the first distance and a depth of the second grooves 270 may be about 1:1.5 to about 1:2.5.

The depth of the second grooves 270 may be about 15 nm to about 40 nm.

If the depth of the second grooves 270 is too large, the isolation between the gate structures 220 and the plugs may be not good. If the depth of the second grooves 270 is too small, the parasitic capacitance between the plugs and the gate structure 220 may be large and the parasitic capacitance of the semiconductor device may not be improved.

In some embodiments, the second grooves 270 may be formed by: forming a mask layer on the second dielectric layer 260 and on the first spacers 203 exposing the bottom of the first spacers 203; and etching the first dielectric layer 250 under the bottom of each first groove 202 to expose the corresponding source/drain doped layer 240 and to form the second groove 270 in the first dielectric layer 250, by using the mask layer and the first spacers 203 as a mask.

The first dielectric layer 250 under the bottom of the first grooves 202 may be etched by an anisotropic dry etching method or an anisotropic wet etching method.

In one embodiment, the first dielectric layer 250 under the bottom of the first grooves 202 may be etched by an anisotropic dry etching method.

As illustrated in FIG. 7, a plug 271 may be formed in each first groove 202 and a corresponding second groove 270 (e.g., Step S812 in FIG. 8).

The plugs 271 may have a top flush with a top f the second dielectric layer 270.

Before forming the plugs 271, a metal silicide layer may be formed on the bottom of each second groove 270. The metal silicide layers may reduce a contact resistance between the plugs 271 and the source/drain doped layers 240.

The metal silicide layers may be formed by: forming a metal layer on the sidewalls and the bottom of each second groove; and annealing the metal layers and the source/drain doped layers 240, to form a metal silicide layer on a portion of the top of each source/drain doped layer 240 exposed by the corresponding second groove 270.

The plugs 271 may be made of a metal including tungsten, cobalt, titanium, and/or nickel.

In one embodiment, the plugs 271 may be made of tungsten.

The plugs 271 may be formed by: forming a plug material layer in the first grooves 202, in the second grooves 270, and on the top of the second dielectric layer 260; and planarizing the plug material layer to expose the top of the second dielectric layer 260 and to form a plug 271 in each first groove 202 and the corresponding second groove 270.

The plug material layer may be formed by a deposition method including a chemical vapor deposition method, a physical vapor deposition method, and/or an atomic layer deposition method.

A parasitic capacitance between the plugs 271 in the first grooves 202 and the gate structures 220 may be a first capacitance, while a parasitic capacitance between the plugs 271 in the second grooves 270 and the gate structures 220 may be a second capacitance. A parasitic capacitance between the plugs 271 and the gate structures 220 may be a sum of the first capacitance and the second capacitance. Since the plugs 271 in the second grooves 270 and the gate structures 220 may be isolated from each other by the dielectric layer, the second capacitance may be small and correspondingly the parasitic capacitance between the plugs 271 and the gate structures 220 may be small. The performance of the semiconductor device may be improved.

The present disclosure also provides a semiconductor device formed by the fabrication method provided by various embodiments of the present disclosure. As illustrated in FIG. 7, the device may include: a substrate 200, gate structures 220 on the substrate 200, source/drain doped layers 240 in the substrate 200 at two sides of each of the gate structures 220, the dielectric layer on the substrate 200 covering the gate structures 220 and the source/drain doped layers 240, first grooves in the dielectric layer at the two sides of each of the gate structures 220 with bottom surfaces lower than top surfaces of the gate structures 220, first spacers 203 on sidewalls of the first grooves; a second groove in the dielectric layer and at the bottom of each first groove, and a plug 271 in each first groove and a corresponding second groove. Each first groove may be connected to the corresponding second groove and the second grooves may expose the source/drain doped layers.

Details of the substrate 200, a structure and a position of the gate structure 220, a material and a position of the source/drain doped layers, and the plugs 271 can be referred to above description.

In the present disclosure, since the first grooves may be close to the gate structures and the plugs in the first grooves have to be isolated better from the gate structures, the first spacers may be formed on the sidewalls of the first groves to improve the isolation between the plugs in the first grooves and the gate structures. A parasitic capacitance between the gate structures and the plugs in the first grooves may be a first capacitance, while a parasitic capacitance between the gate structures and the plugs in the second grooves may be a second capacitance. A parasitic capacitance between the gate structures and the plugs may be a sum of the first capacitance and the second capacitance. Since each gate structure may be isolated from the plug in a corresponding second groove by the dielectric layer, the second capacitance may be small and correspondingly the parasitic capacitance between the gate structures and the plugs may be small. The performance of the formed semiconductor device may be improved.

Various embodiments have been described to illustrate the operation principles and exemplary implementations. It should be understood by those skilled in the art that the present disclosure is not limited to the specific embodiments described herein and that various other obvious changes, rearrangements, and substitutions will occur to those skilled in the art without departing from the scope of the disclosure. Thus, while the present disclosure has been described in detail with reference to the above described embodiments, the present disclosure is not limited to the above described embodiments but may be embodied in other equivalent forms without departing from the scope of the present disclosure, which is determined by the appended claims.

What is claimed is:

1. A fabrication method for a semiconductor device, comprising:
providing a substrate;
forming gate structures on the substrate and source/drain doped layers in the substrate at sides of each gate structure;
forming a dielectric layer on the substrate to cover the gate structures and the source/drain doped layers;
forming a first groove in the dielectric layer on each source/drain doped layer, wherein the first groove has a bottom surface lower than top surfaces of the gate structures;
forming first spacers on sidewalls of each first groove, wherein the first spacers have a dielectric constant larger than a dielectric constant of the dielectric layer;
forming a second groove in the dielectric layer beneath the bottom surface of each first groove, wherein each first groove is connected to a corresponding second groove and exposes a corresponding source/drain doped layer; and
forming a plug in each first groove and the corresponding second groove.

2. The method according to claim 1, wherein:
a distance between the bottom surface of each first groove and the top surface of a corresponding gate structure is a first distance; and
a ratio between the first distance and a depth of the second grooves is about 1:1.5 to about 1:2.5.

3. The method according to claim 2, wherein:
the first distance is about 8 nm to about 25 nm.

4. The method according to claim 1, wherein:
a depth of the second grooves is about 15 nm to about 40 nm.

5. The method according to claim 1, wherein a process for forming the first spacers includes:
forming a first spacer material layer in the first grooves and on the dielectric layer; and
etching back the first spacer material layer until exposing a top surface of the dielectric layer to form the first spacers.

6. The method according to claim 1, wherein:
a thickness of the first spacers is about 3 nm to about 6 nm.

7. The method according to claim 1, wherein:
the first spacers may be made of SiN, SiNB, SiCNO, SiNO, or any combination thereof.

8. The method according to claim 1, before forming the plugs, further including forming a metal silicide layer on a bottom of each second groove.

9. The method according to claim 1, wherein the plugs are made of a metal including tungsten, cobalt, titanium, nickel, or any combination thereof:

10. The method according to claim 1, wherein:
for each first groove, a top size is larger than a bottom size, and the sidewalls and a surface of the substrate form obtuse angles.

11. The method according to claim 1, wherein:
for each second groove, a top size is larger than a bottom size, and the sidewalls and a surface of the substrate form obtuse angles.

12. The method according to claim 1, wherein a process for forming the second grooves includes etching the dielectric layer at the bottom of the first grooves until exposing the source/drain doped layers to form the second grooves in the dielectric layer by using the first spacers as a mask.

13. The method according to claim 12, wherein:
the dielectric layer at the bottom of the first grooves may be etched by an anisotropic dry etching method or an anisotropic wet etching method.

14. The method according to claim 1, wherein a process for forming plugs includes:
forming a plug material layer in the first grooves, in the second grooves, and on the dielectric layer; and
planarizing the plug material layer until exposing the surface of the dielectric layer to form the plugs in the first grooves and the second grooves.

15. A semiconductor device, comprising:
a substrate;
gate structures on the substrate;
source/drain doped layers in the substrate at sides of each gate structure;
a dielectric layer on the substrate covering the gate structures and the source/drain doped layers;
a first groove in the dielectric layer above each source/drain doped layer, wherein the first groove has a bottom surface lower than top surfaces of the gate structures;
first spacers on sidewalls of each first groove, wherein the first spacers have a dielectric constant larger than a dielectric constant of the dielectric layer;
a second groove in the dielectric layer beneath the bottom surface of each first groove, wherein each first groove is connected to a corresponding second groove and exposes a corresponding source/drain doped layer; and
a plug in each first groove and the corresponding second groove.

16. The device according to claim 15, wherein:
for each first groove, a top size is larger than a bottom size, and the sidewalls and a surface of the substrate form obtuse angles.

17. The device according to claim 15, wherein:
for each second groove, a top size is larger than a bottom size, and the sidewalls and a surface of the substrate form obtuse angles.
